(19) United States
(12) Patent Application Publication
(10) Pub. No.: US 2006/0196845 A1
(43) Pub. Date: Sep. 7, 2006

(54) Quartz Tuning-Fork Resonators and Production Method

(75) Inventors: Peter H. LaFond, Redmond, WA (US); Johathan L. Klein, Redmond, WA (US)

Correspondence Address: HONEYWELL INTERNATIONAL INC., 101 COLUMBIA ROAD, P O BOX 2245, MORRISTOWN, NJ, 07962-2245, US

(73) Assignee: HONEYWELL INTERNATIONAL INC., Morristown, NJ (US)

(21) Appl. No.: 10/906,767

(22) Filed: Mar. 4, 2005

(51) Int. Cl. C23F 1/00; C23C 14/00; H01L 21/306

(52) U.S. Cl. 216/41; 156/345.3; 204/192.34

(57) ABSTRACT

Methods and apparatus for producing crystalline Quartz tuning-fork resonators using a deep reactive ion etching process. The resonators have an outline formed by a method including masking a substrate with a metal mask. The metal mask being resistant to reactive ion etching and conforming to the outline. The resulting plasma etched resonators are strong and have a high degree of symmetry, which substantially reduces common critical performance errors occurring in accelerometers, pressure sensors, tilt meters, scales, and rate gyroscopes.

### BACKGROUND OF THE INVENTION

Quartz resonators are widely used in sensors. Crystalline quartz has two qualities that make it particularly attractive for resonator use; it is a high-Q material and is a piezoelectric material. The high-Q material leads to good resonator sensitivity and stability and the piezoelectricity leads to a simple and a robust oscillator, of which the resonator is the mechanical portion.

In one class of tuning-fork resonators, a resonator is placed in a sensor so that it serves as the “principal support”. In operation, it is subjected to an axial force as it supports a proof mass, a diaphragm, or some other mechanical feature within the sensor. In this configuration, it can be used in accelerometers, pressure sensors, force-sensors, and tilt-meters. In these applications, an axial force in the resonator modifies the frequency of one of the fundamental flexural modes of vibration of a double-ended tuning fork. The frequency, when measured, is then used to calculate a corresponding acceleration, pressure, tilt or force.

A second class of resonators makes use of a Coriolis force and are configured to be sensitive to a rotation, usually about the tuning-fork axis. This leads to its use in rate gyros. Here, a fixed-amplitude, in-plane, resonant drive mode, interacting with a rotation about the tuning-fork axis, causes a portion of the resonator to vibrate orthogonal to both the resonant drive velocity and angular rate axis (i.e., an out-of-plane vibration is induced). The displacement of this induced out-of-plane motion produces a signal which, when measured, is used to determine the rate of rotation.

Although the operating principles of these two general classes of quartz resonators have their differences, many of the limitations on their performance are due to the same resonator geometry imperfections. These geometry imperfections, in turn, are primarily due to the fabrication method currently in use.

A key determinant of the performance of resonators is the degree of coupling between the resonator and the structure to which it's mounted. Since coupling leads to lost energy, minimizing this mechanical coupling improves the Q-factor of the resonator and so improves the stability of the sensor. More importantly, low coupling provides immunity to “activity dips”, which are a type of error in resonators. Under conditions where the resonator frequency is near that of a resonance in the frame to which it is attached and couples, a slight undesired deviation in the expected resonator frequency will be produced. Since the DETF frequency is the indicator of the sensor's output, an error results. The level of coupling, and thus the sensor error, can be reduced by designing a dynamically balanced resonator where the reaction moments and forces are zero at its support pads.

FIG. 1 illustrates a plot of DETF frequency vs. acceleration input for an accelerometer having unwanted facets. As the applied acceleration is increased from 0 to 40 g's, the DETF frequency increases nearly linearly, as shown. The “frequency error” line is the deviation of this DETF output frequency from a least-squares fit.

A local non-linearity (activity dip) near 10 g's is clearly evident, and a frequency error of up to 15 Hz results. This occurs where the DETF frequency crosses a mode within the structure to which it is attached; in this case, at about 35400 Hz.

A portion of a prior art DETF 12, typical in acceleration sensing, is shown in FIG. 2. It was produced by standard wet chemical etching (HF acid) and represents the prior art. The DETF 12 includes a “crotch” region 18 where the tines are joined and which plays an important part in de-coupling the resonator from its surroundings.

Conventionally, the DETF 12 is fabricated from a z-cut quartz wafer. The wafer is wet etched, using photolithography to define the geometry. Conductive plating is then patterned on the DETF tine surfaces to form an electrode 24 with two terminals, the terminals being configured to receive a voltage to excite a piezoelectric resonator. Additionally, traces 28 are routed to conduct current to the electrodes 24. When excited, the resonator oscillates at a frequency mainly determined by the geometry of the DETF and the axial load applied by the end mounting pads. For example, when the DETF supports a proof mass and acceleration is applied to that proof mass, an axial load (either tension or compression) appears in the DETF tines. This axial load changes the DETF flexural frequency, which when measured, can be used to determine the applied acceleration.

Wet etch processing, although inexpensive, cannot produce DETFs without compromising DETF geometry in ways that lead to lowered performance. Quartz has a crystalline geometry that produces facets during wet etching. These facets 15 are not symmetric about the principal planes of the DETF 12. A critical region of the DETF 12 is the “crotch” region 18 where the two tines join near the mounting pads. Many facets 15 are formed in the corners of the crotches. Facets also may appear on the tine side walls.

Referring to FIG. 2, a facet 15 includes a sharp edge located in a high-stress region of the DETF 12; the facet 15 serves as a “stress raiser” and thus lowers the fracture strength of the crystalline DETF 12. Lowered strength means either that the DETF 12 can't survive the seismic loads expected in a given application, or it has to be “beefed up” to withstand the loads and thus sacrifice sensitivity. More importantly, non-symmetry of the DETF 12 resulting from the presence of facets 15 allows mechanical coupling to the surroundings via non-zero reactions at its mounting pads. This leads to the “activity dips” errors previously discussed.

Rate Gyros

Quartz tuning-fork resonators as used in gyros do not use a measured frequency as an indication of the input rotation rate, but use an out-of-plane displacement signal as a measure of rate of rotation. Configurations which have been developed are:

1. A single-ended tuning-fork (SETF).

2. Two SETFs joined at their bases (an “H” configuration).

3. SETF with more than two tines.

In a first configuration, an electrode pattern on a portion of each tine of the SETF drives the tines in-plane and in opposition, just as in a DETF. Another portion of each tine has a different electrode pattern which serves as a pick-off of out-of-plane, out-of-phase tine bending. With perfect SETF geometry, there is no out-of-plane motion in the absence of rotation about the resonator axis. With superimposed rotation, a Coriolis acceleration causes an out-of-plane component to the tine vibration which is sensed and used as an indication of rotation rate.

A 2^{nd} configuration places the drive on one tuning-fork and uses another fork to sense out-of-plane bending. The two SETFs are joined at their bases and to a supporting frame in such a way that twisting of the driven fork about its axis is transmitted to rotation of the 2^{nd} SETF. The out-of-plane, out-of-phase bending that occurs in these sense tines are detected and use as an indication of rotation.

As with axial-force resonators, these gyro resonators rely on symmetry to achieve good performance. Facets almost always represent non-symmetry and often result in the driven mode having an unwanted out-of-plane component, which gets detected by the sense section of the resonator. This produces a bias error, called “quadrature”; an apparent rotation with zero input rotation. This quadrature error is nominally 90 degrees out of phase with the Coriolis-induced motion so, in theory, synchronous demodulation will allow separation of the desired signal from the quadrature signal. But in practice, the quadrature signal is very large, so that even with the best demodulation that can be achieved, an unacceptably large error signal often remains. The usual strategy employed to reduce the quadrature error further is to deposit metal near the tips of the tines and use laser trimming to selectively remove part of this metal, actively tweaking the quadrature error in an attempt to minimize bias error. Unfortunately, as this process reduces one problem, it creates a new one. Although a twisting motion that this process introduces can help to null quadrature, other mass imbalance is created which increases reactions at the resonator mounts, leading to activity-dip induced errors. Activity dips in rate gyros typically show as a local non-linearity in the scale factor vs. temperature relation. Only by producing a high degree of symmetry can a low quadrature error and insensitivity to potential activity dips be achieved.

What is needed in the art is a method of fabricating these quartz resonators without facets that destroy the symmetry and create an unwanted out-of-plane component in the drive motion, since this component will be picked up by the sense tines and interpreted as rotation.

### BRIEF SUMMARY OF THE INVENTION

In this invention, piezoelectric tuning-fork resonators are chemically milled by “dry” plasma etching, also known as deep reactive ion etching (DRIE). The most common material choice is quartz, although other piezoelectric materials can be used. The resonators have an outline, formed by a method including masking a substrate with a mask, the mask being resistant to reactive ion etching and conforming to the outline. The flow of etch plasma is removed when the trenches breach the substrate to release the formed flexural resonator.

Plasma etching produces vertical walls, without facets, and can be optimized for any given nominal resonator geometry to achieve symmetry about all three principal planes of the resonator. Symmetry about the resonator's mid-plane is especially important. A stronger structure results because “stress riser” facets in the high-stress crotch region are eliminated.

### BRIEF DESCRIPTION OF THE SEVERAL VIEWS OF THE DRAWING

The preferred and alternative embodiments of the present invention are described in detail below with reference to the following drawings.

FIG. 1 is a graph that illustrates an “activity dip” in DETF formed in accordance with the prior art;

FIG. 2 is a diagram of a prior art double-ended tuning-fork formed in accordance with the prior art;

FIG. 3 is a flow chart of a DRIE process formed in accordance with an embodiment of the present invention;

FIG. 4 is a close-up view of vertical walls of a tuning fork produced by the process shown in FIG. 3;

FIG. 5 is a perspective view of a DETF formed by the process shown in FIG. 3;

FIG. 6 is a drawing of a SETF rate gyro;

FIG. 7 is a drawing of a rate gyro employing two SETFs joined at their bases;

FIG. 8 is a drawing of a 4-tine rate gyro; and

FIGS. 9 and 10 are drawings of a 3-tine rate gyro.

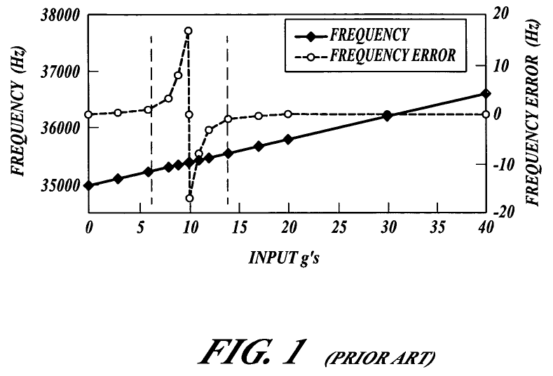

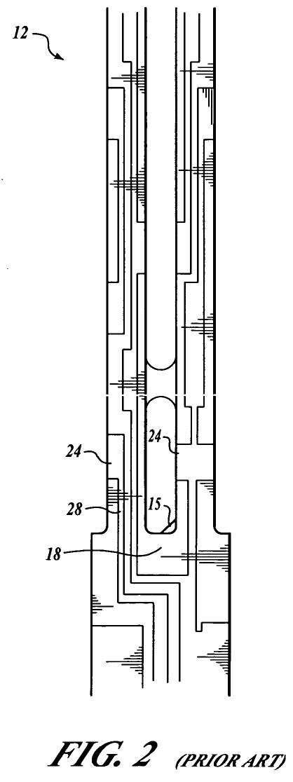

### DETAILED DESCRIPTION OF THE INVENTION

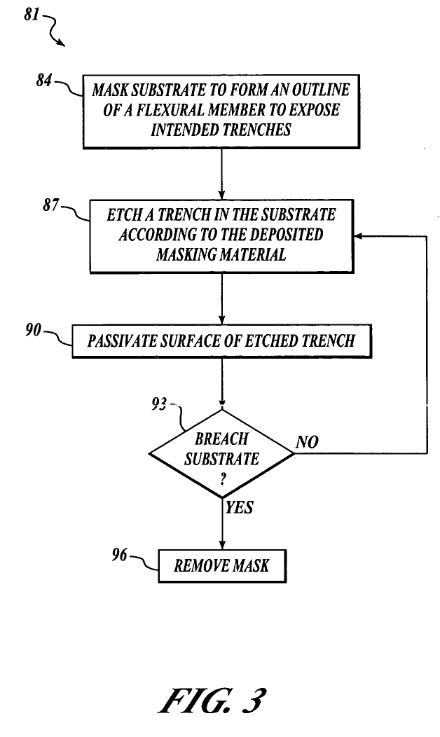

In FIG. 3, a deep reactive ion etching (DRIE) process 81 is shown. In one presently preferred approach to DRIE etching, high-density plasma with an optimize gas mixture is used. At a block 84, a piezoelectric substrate (such as crystalline Quartz (SiO₂)) is masked with a non-reactive mask, such as nickel or other comparable metal. The mask forms an outline of a flexural member to expose intended trenches. The mask protects the substrate by forming an etching shadow. At a block 87, a plasma source etches the substrate to form a trench that outlines the DETF, thus removing the material including granules in a crotch region (that might compromise the performance of the DETF. The plasma-to-wafer potential bias is set so that the ions which are attracted to horizontal surfaces of the substrate result in enough reaction energy to allow the ions to chemically react with the surface. The plasma gas species and mixtures are chosen to create charge-neutral volatile molecules when they chemically combine with the surface at the elevated reaction energies. These charge-neutral volatile molecules are removed from the plasma-etching chamber by a vacuum pump.

The gas species and mixtures are also chosen such that at the reaction energies seen by the vertical surfaces or the trench sidewalls, create no volatile molecules, and therefore, do not etch the sidewalls. A slight variation is sometimes also used where, at the lower reaction energies of the sidewalls, a deposition occurs and provides a sidewall protective layer. This protective layer prevents physical sputtering from eroding the sidewalls, though such sputtering occurs to some extent in all plasma etching. These techniques can result in very deep etched trenches and minimal sidewall attack.

In one embodiment, at the block 87, an inductively-coupled plasma (ICP) source is employed to etch the substrate using nickel as the mask. By using ICP or ICP systems, the radio frequency energy is coupled into a low pressure gas by an inductive coil mounted on the outside of a vacuum plasma etch chamber. ICP etchers produce relatively low ion energies and so biasing of the substrate being etched may be used to tailor ion bombardment energies tuning the degree of anisotropy of the resulting etch.

At a block 90, the etched trench is passivated. At a block 93, the substrate is examined for properly formed DETF structures. If the DETF is suitably formed, the mask is removed at a block 96, otherwise the process returns to the block 87.

Plasma-based etching is done in plasma chemical reactors that includes a vacuum chamber, power supply, and gas handling system. In the plasma, the gas-phase chemical compounds are separated into neutral fragments, positive and negative ions, and electrons. In a typical directional etch plasma system, a bias is applied to the wafer to attract and removed charged ions from the plasma and accelerate them toward the wafer's surface. Depending on the ion species and acceleration energy, a combination of three interactions occur with the wafer's surface. (1) The energy of the ions are low enough that any chemical reaction that occurs with the wafer's surface results in a non-volatile compound which stays and continues to grow. This process is commonly refereed to as Plasma Enhanced Chemical Vapor Deposition (PECVD). (2) The energy of the ions upon hitting the wafer's surface are in the correct range that the resulting chemical reaction creates a volatile compound which is pumped away by the vacuum system. This process is commonly referred to as Reactive Ion Etching (RIE). (3) The energy of the ions hitting the wafer's surface is so high that parts of the wafer's surface is sputtered off with very little or no chemical reactions. This process is commonly referred to as sputtering. In one embodiment, the DRIE process is magnetically enhanced

Optimizing a plasma etch system for a vertical feature requires selection of a gas to etch the material, setting of the wafer bias so that the correct chemical reactions occur that result in material removal, and selection of the masking material protecting those areas of the wafer's surface not to be etched.

Typically fluorocarbon gases are used to etch quartz. The positive ions of the fluorocarbon gas in the plasma are attracted to the negatively charged wafer and accelerate. Those areas of the wafer's surface not protected by a mask are bombarded and therefore etched by the ions. A combination of the direction of the wafer bias created electric field and lack of collisions en route makes the ions bombard the wafer surface vertically—thus providing more ions and reactive energy to the horizontal surfaces than on the forming sidewalls defined by the edges of the masking material. A vertical feature will evolve from areas not masked with a chemically inert material.

Advantageously, tuning fork resonators are generally fabricated from monocrystalline quartz material. The chemical composition of quartz is SiO₂. The Si atoms are in four-coordination with oxygen and constitute the (SiO₄) tetrahedron, which is the basic unit of the structure. Each oxygen is shared with two Si atoms. Quartz belongs to the trigonal-trapezohedral class of the rhombohedral subsystem. The lattice type is hexagonal. This class is characterized by one axis of three-fold symmetry and three polar axes of two-fold symmetry perpendicular thereto and separated by angles of 120 degree. There is no center of symmetry and no plane of symmetry. Although quartz is most often the material of choice for resonators, other piezoelectric materials can be used.

The axes of reference (X, Y, Z) are chosen such that X is one of the axes of two-fold symmetry and Z is the axis of three-fold symmetry with relation to the quartz molecule. Cutting a quartz crystal along different planes will result in wafers with various distinct properties. One commonly used wafer is cut out of a quartz crystal along the X-Y plane, perpendicular to the Z axis, and is commonly called a Z-cut wafer. It is difficult to chemically machine quartz due to its inertness. Strong hydrogen fluoride (HF) based etchants are normally used. With these, the etch rate along the Z-axis is much faster than in the XY-plane, because of the elongated crystalline structure along that axis. Exploiting that difference in the crystalline structure has allowed high aspect ratios.

Referring to FIG. 4, a cross-section of an etched sidewall 69 is shown. The sidewall 69 has a designed vertical boundary 75. The closer the sidewall 69 approximates the vertical boundary 75, the better the performance of the resulting DETF. Smooth local irregularities as shown in FIG. 4 are acceptable as long as overall symmetry about the mid-plane is maintained.

Because the inventive technology obviates any further machining or finishing, these DETFs can also be formed as integral quartz assemblies, including one or more DETFs, a proof mass or diaphragm, and a supporting frame. Minor laser trimming can, however, be done following resonator fabrication according to this invention, to further improve performance.

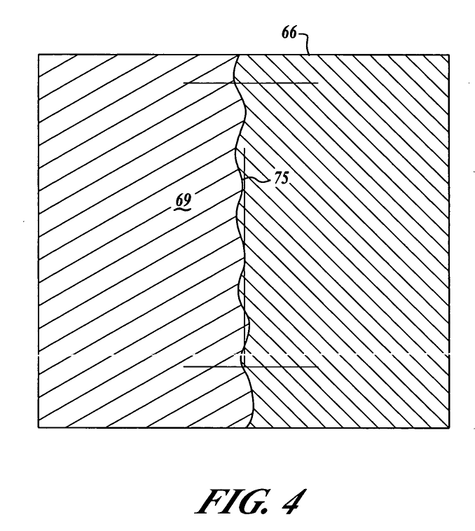

A double-ended tuning-fork (DETF) resonator is the simplest form of an axially-loaded, dynamically balanced structure, used in instruments such as pressure sensors & accelerometers. The DETF resonator includes two parallel tines joined at both ends, where enlarged mounting pads are located. As shown in FIG. 5, several resonators are shown, each connected by break-out tabs to its supporting wafer. After completion of fabrication, the resonators are broken out at the tabs and installed in a sensor assembly. The resonator pads join the resonator to the remainder of the mechanical structure which, along with electronics, makes up the sensor. This DETF is part of an electro-mechanical oscillating system. The other part of the system is an electrical feedback network, which drives the tines to vibrate in the plane of the resonator and in opposition to each other. One of a number of deposited metal electrode patterns, which are well known in the field, is applied to the surfaces of the resonator tines. When these electrodes are connected to suitable oscillator electronics, operation will cause the resonator to vibrate at its in-plane, anti-phase resonant mode. An applied axial force will shift this resonant frequency in response to the force (tension increases the frequency, compression causes a decrease).

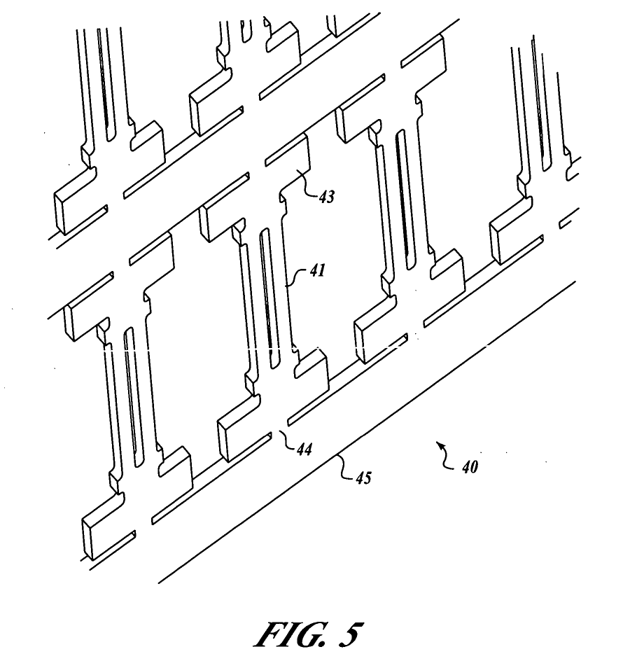

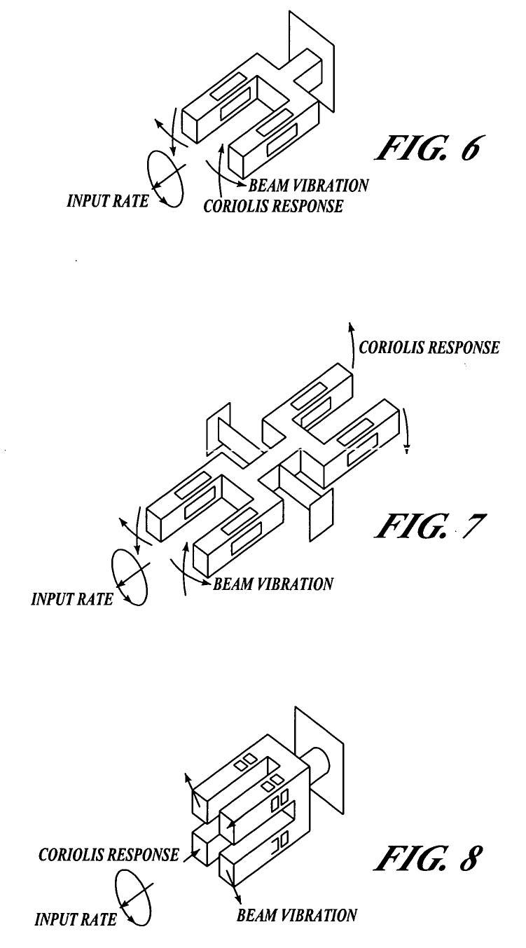

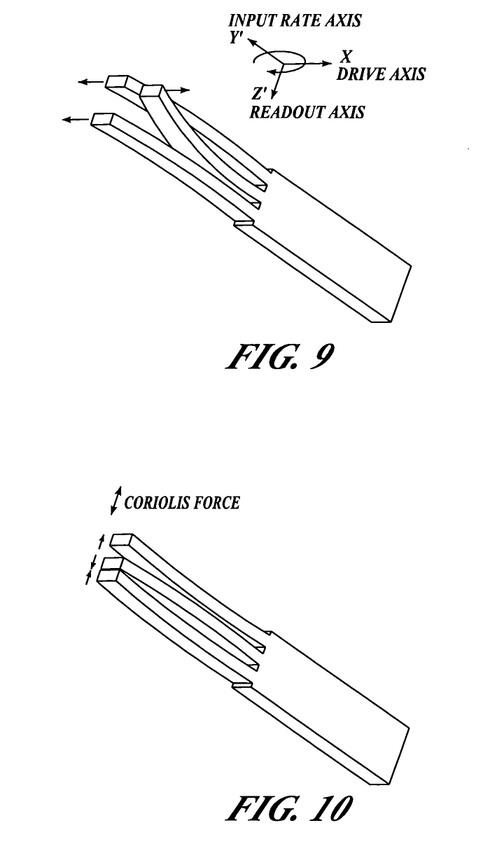

The present invention may be used to generate Single-ended tuning-fork (SETF) gyros, such as that shown in FIGS. 6 and 7. Also, SETF gyros with more than two tines, joined at a base, can be fabricated using the process described above (see FIGS. 8-10 for 3-tine and a 4-tine configurations). Configurations with tapered tines and with tines which are not parallel can also be manufactured using the present invention.

While the preferred embodiments of the invention have been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

What is claimed is:

1. A method of producing a resonator, the method comprising:
applying a mask to a piezoelectric substrate;
deep reactive ion etching the unmasked substrate to a predefined depth; and
removing the mask,
wherein the unetched substrate forms a resonator.

2. The method of claim 1, wherein the piezoelectric substrate is quartz.

3. The method of claim 1, wherein the resonator includes two tines and is double-ended.

4. The method of claim 1, wherein the resonator includes more than two tines and is double-ended.

5. The method of claim 1, wherein the resonator includes two tines and is single-ended.

6. The method of claim 1, wherein the resonator includes more than two tines and is single-ended.

7. The method of claim 1, wherein the resonator includes two single-ended tuning-forks having bases, wherein the two single-ended tuning-forks are joined at the bases.

8. The method of claim 1, wherein etching is magnetically enhanced.

9. A system of producing a resonator, the system comprising:
a first component configured to apply a mask to a piezoelectric substrate;
a second component configured to deep reactive ion etch the unmasked substrate to a predefined depth; and
a third component configured to remove the mask,
wherein the unetched substrate forms a resonator.

10. The system of claim 9, wherein the piezoelectric substrate is quartz.

11. The system of claim 9, wherein the resonator includes two tines and is double-ended.

12. The system of claim 9, wherein the resonator includes more than two tines and is double-ended.

13. The system of claim 9, wherein the resonator includes two tines and is single-ended.

14. The system of claim 9, wherein the resonator includes more than two tines and is single-ended.

15. The system of claim 9, wherein the resonator includes two single-ended tuning-forks having bases, wherein the two single-ended tuning-forks are joined at the bases.

16. The system of claim 9, wherein the second component performs magnetically enhanced etching.
